(19) United States
(12) Patent Application Publication
(10) Pub. No.: US 2008/0309867 A1
(43) Pub. Date: Dec. 18, 2008

(54) PROCESS FOR FABRICATING A FLEXIBLE ELECTRONIC DEVICE OF THE SCREEN TYPE, INCLUDING A PLURALITY OF THIN-FILM COMPONENTS

(76) Inventor: Vida Kampstra, VOIRON (FR)

Correspondence Address: BRINKS HOFER GILSON & LIONE, P.O. BOX 10395, CHICAGO, IL, 60610, US

(21) Appl. No.: 12/094,521

(22) PCT Filed: Nov. 20, 2006
(86) PCT No.: PCT/FR06/02543

§ 371 Date: May 21, 2008

(30) Foreign Application Priority Data
Nov. 22, 2005 (FR) 0511798

(51) Int. Cl. G02F 1/1333; B32B 37/00; B32B 17/06; G02B 26/00; H01J 9/26; H01J 1/62

(52) U.S. Cl. 349/158; 156/247; 428/426; 445/24; 313/511; 359/296

(57) ABSTRACT

In the fabrication of a thin-film flexible electronic device of the screen type that includes a plurality of thin-film components on a glass support a starting support is prepared, including a rigid bulk substrate and a glass sheet fastened to the rigid bulk substrate by reversible direct bonding so as to obtain a removable interface. The plurality of thin-film components are fabricated on the glass sheet. The glass sheet is separated from the rigid bulk substrate by disassembling the interface and, the glass sheet and the plurality of thin-film components are transferred to a final support.

### PRIORITY CLAIM

This application is a U.S. nationalization of PCT Application No. PCT/FR2006/002543, filed Nov. 20, 2006, and claims priority to French Patent Application No. 0511798, filed Nov. 22, 2005.

### TECHNICAL FIELD

The invention concerns an electronic device, of the active or passive matrix screen type, comprising electronic components in thin layers on a thin support and offering good performance from the point of view of flexibility and/or lightness and/or robustness.

### BACKGROUND

Active matrix screens are usually LCD screens, but more recently there have appeared screens referred to as electrophoretic screens and electroluminescent screens of the type employing organic light-emitting diodes (OLED) or of the polymer-based PLED type. All these screens employ an active matrix based on TFT (Thin-Film Transistor) components and other thin layer components (thin layer diodes in particular) produced from amorphous silicon or polycrystalline silicon on a glass plate of large area and with a thickness of the order of 0.7 mm.

For applications to portable equipments (telephones, PDA, computers, and the like) manufacturers are demanding lighter and lighter screens. Another feature required for screens or thin layer electronic devices is flexibility, for simpler integration into new products, or even to make possible new applications such as an orientation card or a roll-up screen, in particular. A final feature looked for is robustness. The fragile nature of current LCD screens based on thick glass imposes the addition of a plastic protection layer to portable devices. It would be desirable to dispense with these. Whether the requirement is for greater lightness, greater flexibility or greater robustness, the aim is to dispense with the thick and rigid glass support plate, in practice 0.7 mm thick, or even two glass plates as in the case of LCD screens in which a colored filter also rests on this support.

To this end it has been proposed to provide these active matrices on a plastic support, which combines lightness and flexibility.

A number of approaches have therefore been proposed:

direct fabrication on plastic: this technique has at least two drawbacks, however: (i) the necessity to reduce the processing temperatures during the various fabrication process steps (because of the poor thermal stability of the plastic) and therefore reduced TFT performance, and (ii) delicate manipulation of the plastic substrates during fabrication (because of their lack of stiffness, and the like), whence an incompatibility with existing fabrication lines in the case of glass supports;

by fabrication on a support followed by transfer to another support, including in particular the prior art “SUFTLA” and “EPLAR” processes.

The “SUFTLA” process from Seiko-Epson (described in particular in the document “SUFTLA® (Surface Free Technology by Laser Ablation/Annealing)”, S. Utnunomiya et al.—TFT2-1 in AM=LCD'02—pp. 37-40) includes the following steps: (i) fabrication on a 0.7 mm glass plate of polycrystalline silicon TFT components, and (ii) transferring the components onto an intermediate support using an amorphous silicon sacrificial layer deposited beforehand between the TFT stack and the glass support, followed by transfer to a plastic material final support. Bonding to the intermediate support and then to the plastic support is effected by means of a water-soluble resin in the former case and an adhesive in the latter case.

This process necessitates that the first support (on which the components are fabricated) be transparent at the wavelength of the laser used to reach the sacrificial layer and partially to destroy it (in practice by heating the amorphous silicon). Furthermore, this process is costly since it uses amorphous silicon, a laser and two transfers; there can also be problems assembling an LCD device with two flexible plastic films. Moreover, laser technologies are difficult to transfer to large dimensions (which is necessary for screens of meaningful size) and bonding to polymers is subject to problems of aging.

The “EPLAR” process from Philips (see in particular the document 54-2: Thin Plastic Electrophoretic Displays Fabricated by a Novel Process, SID 05 DIGEST—pp. 1634-1637) does not use amorphous silicon either, but a layer of polyimide. To be more precise, this process includes the following steps:
(i) depositing on a 0.7 mm thick glass support a polymer layer a few microns thick,
(ii) fabricating amorphous silicon TFT components,
(iii) depositing organic LED layers,
(iv) separating the support and the polyimide layer: the latter becomes the layer holding the TFT components.

This process is simpler than the “SUFTLA” process (there is only one transfer) but is still costly because the separation step uses a laser separation technique. Furthermore, the necessity to fabricate the TFT components on a polymer layer affects compatibility with existing processes, treatments and fabrication lines, as well as their performance (in particular: necessity for a low PECVD temperature, for the insulator and semiconductor layers, compromising the quality of those layers, problems with obtaining correct flatness, leading to stresses in the finished device).

In addition to the drawbacks mentioned above, note that neither of these two processes has until now led to mass production, essentially because of the difficulty in applying them to screens of large size (typically more than 50 mm diagonal). Moreover, these two techniques do no allow bottom emission (downward emission) because of the residual presence in the final stack of the amorphous silicon layer or the polyimide layer (see the diagrams in the SUFTLA and EPLAR documents).

### SUMMARY

This is why a general object of the invention is a process for fabricating a screen type electronic device, which can be of large size, including a plurality of thin layer electronic components that is light in weight and flexible, whilst employing proven techniques of moderate cost, compatible with large sizes. It is more particularly directed to a process for fabricating passive or active matrix screens (with thin layer components—of TFT type—with pixels of OLED, LCD or electrophoretic type, among others), that are light in weight and flexible, simple and of moderate cost.

To this end the invention proposes a process for fabricating a screen type thin layer electronic device including a plurality of thin layer components on a glass support, the method including steps whereby:

1) a starting support is prepared including a rigid bulk substrate and a glass film attached to the rigid bulk substrate by reversible direct bonding to obtain a debondable interface,

2) the plurality of thin layer components is fabricated on this glass film,

3) the glass film on which the plurality of thin layer components has been fabricated is separated from the rigid bulk substrate by debonding the interface. The glass film and the plurality of thin layer components are advantageously transferred onto a final support.

The present invention therefore combines the advantages of existing technologies using a rigid glass support (the starting support is of glass, at least where the film is concerned), whilst achieving good control of the final lightness and flexibility, through accurate control of the thickness of the glass film, which thickness can be sufficiently small to obtain the required lightness and flexibility.

In the particular case of fabricating active matrix screens, the process of the invention can be described as including the following steps:

1) a starting support is prepared including a rigid bulk substrate and a glass film fastened to the rigid bulk substrate by reversible bonding so as to obtain a debondable interface,

2) an active matrix of pixels is fabricated on this glass film,

3) a display layer is fabricated on top of this active matrix,

4) the glass film on which the active matrix and the display layer have been fabricated is separated from the rigid bulk substrate by debonding the interface,

5) this glass film, the active matrix and the display layer are transferred onto a final, possibly flexible, support.

This process can therefore produce flexible active matrix screens using existing standard fabrication processes and guarantee the performance of such screens. The advantages of the performance of the TFT on glass technology and the flexibility resulting from control of the thickness of the glass are retained.

It will be realized that the aforementioned screen fabrication processes would lead the person skilled in the art to conclude that the production of flexible screens would imply that the support carrying the thin layer electronic components would be of plastic material.

It will further be realized that the principle of a debondable interface is already known in the art, in particular from PCT patent publication no. WO-02/084722. The teachings of that document concern primarily the case of a silicon substrate on a block of silicon, although it refers to the general case of semiconductor materials such as silicon, germanium or compounds of silicon and germanium, even carbides or nitrides of those elements, or even ferro-electric, piezo-electric or magnetic materials.

However, although the above document proposes applications in the field of screen fabrication, it had not at that time been recognized that its teachings were applicable to a thin and flexible layer of glass (there was indeed provision for the interface to be provided between silicon oxide layers, but these were very thin layers carried by substrates of other materials), and that the choice of that material was compatible, for sufficiently small thicknesses, both with the fabrication of the components and with achieving good flexibility.

In other words, the invention stemmed in particular from the observation that, in contrast to what the “SUFTLA” and “EPLAR” processes might suggest, using a glass support in the final structure of a screen type flexible electronic device was possible, provided that a sufficiently thin film was selected for that support, which was possible, in particular on drawing inspiration from the teachings of PCT patent publication no. WO-02/084722.

Generally speaking, according to preferred features of the invention, where appropriate combined:

1) the starting support is prepared by reversibly bonding the glass film to a rigid glass support, which makes the assembly very stable, in particular mechanically and thermally stable,

2) the reversible direct bonding is in practice molecular bonding, the performance of which can be very good,

3) the reversible direct bonding is preceded by a preparation treatment adapted to render the surfaces to be bonded hydrophilic, which contributes to very good bonding,

4) the surfaces to be bonded have a roughness less than 1 nanometer, preferably less than 0.5 nanometer, which contributes to very good bonding,

5) the starting support is prepared by bonding to the rigid bulk support a glass plate to which a thinning treatment can subsequently be applied, reducing the thickness of the plate to a required value, which means that the film does not have to be manipulated on its own when it has its final thickness,

6) the thin glass film has a thickness at most equal to 100 microns, preferably at most equal to 50 microns,

7) the plurality of thin layer components is fabricated in a step whereby an active matrix of pixels is fabricated on the thin glass film and a step in which a display layer is fabricated on top of this active matrix of pixels, whereby an active matrix screen is obtained after separation,

8) the active matrix of pixels is fabricated by forming TFT components in thin layers, which is achievable with high performance at low cost,

9) the display layer is fabricated by forming organic electroluminescent components of OLED type, which is also achievable with high performance at low cost,

10) an electrophoretic layer is deposited by a rolling process to obtain an electrophoretic screen;

11) an LCD screen is produced,

12) the glass film is separated from the rigid bulk support by inserting a blade, which enables clean separation, without having to heat the assembly, as it can be effected at room temperature,

13) the glass foil and the components that are formed thereon are transferred to a flexible plastic material film (this is known in the art); alternatively, the glass foil and the components that are formed thereon are transferred to a flexible metal foil.

The invention also relates to a screen type device obtained by the above method, in particular, a flexible thin layer electronic device of the screen type including a plurality of thin layer electronic components on a glass support the thickness whereof, at most equal to 100 microns, or even 50 microns, imparts significant flexibility to it.

It is directed in particular to an active matrix screen including active matrices including thin layer components on a glass film whose thickness, preferably at most equal to 100 microns, or even at most equal to 50 microns, imparts significant flexibility to it.

Thus the invention aims to protect a device of the aforementioned type in which the plurality of components advantageously includes a layer formed of an active matrix of pixels and a display layer covering the active matrix of pixels.

In other words, the flexible electronic device of the invention is advantageously an organic light-emitting diode screen, an electrophoretic screen or an LCD screen. The electronic device is advantageously such that the electronic components are designed to emit light through said glass film.

The invention finally proposes a starting support adapted to the fabrication of a thin layer flexible electronic device of the screen type including a rigid bulk substrate and a glass film fastened to that rigid bulk substrate by reversible direct bonding to obtain a debondable interface.

At least the surface of the rigid substrate is advantageously of glass.

### BRIEF DESCRIPTION OF THE DRAWING

Objects, features and advantages of the invention emerge from the following description, which is given by way of illustrative and nonlimiting example, in which:

FIG. 1 illustrates a thin layer electronic device of the invention, here consisting of an active matrix screen,

FIG. 2 illustrates a starting support,

FIG. 3 illustrates a subsequent fabrication step in accordance with the invention of the active matrix of the screen on the support from FIG. 2,

FIG. 4 illustrates another subsequent step of the fabrication of the screen,

FIG. 5 illustrates a separation step involved in the fabrication of the screen,

FIG. 6 illustrates the result of this separation step, and

FIG. 7 illustrates the final result of the fabrication of the screen.

### DETAILED DESCRIPTION

The figures represent by way of example of a thin layer electronic device of the invention an active matrix screen with OLED pixels and a process for fabricating it.

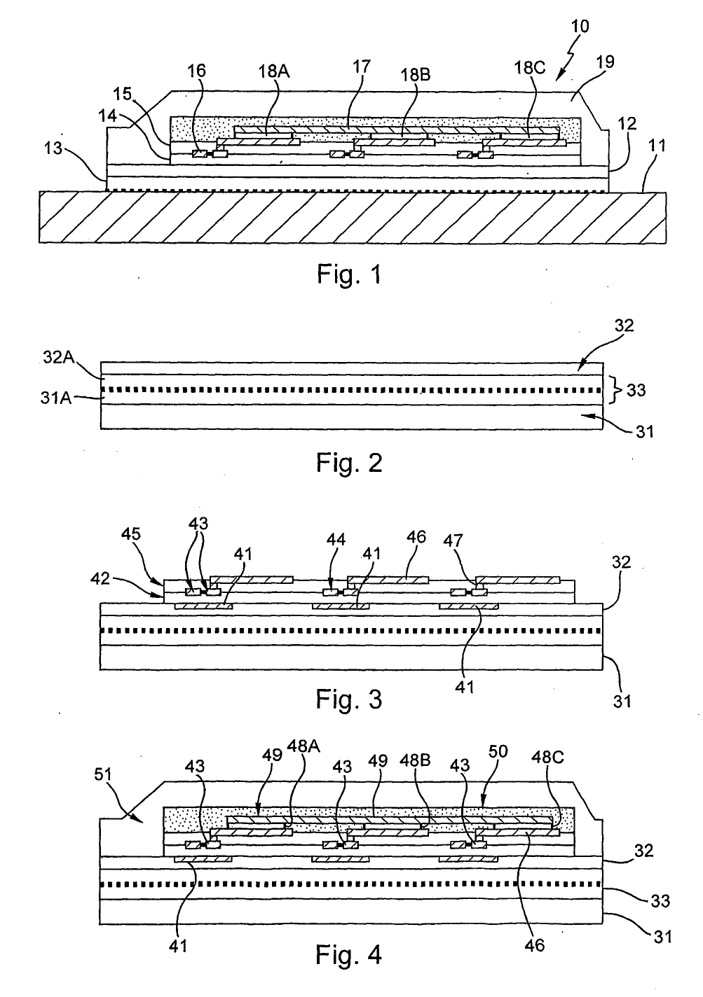

Thus FIG. 1 represents an active matrix OLED screen that is flexible, light in weight and robust.

In this example, the active matrix (in particular, the layer in which the components are produced) is made from amorphous silicon; however, it will be readily apparent that the process of the invention is compatible with temperatures much higher than those involved in the formation of the amorphous silicon by the PECVD process.

To be more precise, this screen 10 includes a final support 11, a thin layer 12 attached to that final support, here by means of an intermediate area 13, two insulative layers 14 and 15 within which contacts 16 are produced, an encapsulation layer 17 covering light-emitting components 18A, 18B and 18C, and a protection layer 19. In practice there are a metal grid and rear contacts, not shown, between the layers 12 and 14.

According to one particular important feature of the invention, the layer 12 is a thin glass layer, for example, a layer with a thickness of at most 100 microns, preferably at most 50 microns, so that the flexibility of the assembly is defined by the flexibility of the support 11.

An advantage of the FIG. 1 device is therefore that it can be fabricated using techniques for depositing thin layers on a substrate formed of glass, at least at the surface, without it being necessary afterwards to dissociate the components from the glass.

FIGS. 2 to 7 show how this screen 10 can be fabricated in accordance with the invention.

This screen fabrication process can be described succinctly by the following steps:

1) fabrication of a starting substrate consisting of a stack of a thin glass film and a rigid film, advantageously also made of glass, the two being temporarily fastened together by reversible direct (molecular) bonding to form a debondable interface;

2) fabrication of an active matrix of pixels on that substrate;

3) fabrication of a display layer on top of the active matrix of pixels,

4) separation of the rigid glass support,

5) transfer of the screen onto a holding support, which can be flexible, if necessary.

The above steps are described in detail hereinafter.

### Production of a Basic Substrate

The basic substrate is fabricated from two glass plates 31 and 32 the shape and size of which are relatively unimportant, depending on the target application for the final device. However, the thicknesses of these plates are chosen to satisfy a number of criteria:

1) the total thickness of the two plates is such that the combination thereof can be manipulated, typically at least equal to approximately 0.4 to 0.7 mm, for example, for an area of the order of 4 m²,

2) the bottom plate 31 has sufficient thickness for this bulk plate to be rigid.

For example, two plates of borosilicate glass are used, of 100 or 200 mm diameter, 0.7 mm thick and with a roughness of 0.2 nm (as measured by AFM over fields of (1×1) μm²).

These plates are intended to be temporarily fastened together. To this end, their roughness is advantageously at most equal to one nanometer, preferably of the order of 0.5 nm or less, which is favorable for good molecular bonding of the facing faces of the plates 31 and 32. If necessary, specific layers can be deposited to obtain the required surface roughness. That roughness can be chosen to enable subsequent debonding at the bonding interface.

The bottom plate, the function of which is to be rigid and to withstand well subsequent component fabrication treatments, can be made from a wide variety of materials. However, as indicated above, it is advantageous if it is also made of glass, preferably a glass with the same properties as that of the top plate in order to avoid thermal expansion problems, for example a standard borosilicate glass as used in the LCD industry.

In practice these plates are cleaned to remove particulate, organic or metallic contamination. This cleaning can be of chemical (wet or dry), thermal, chemical-mechanical polishing or any other type capable of efficiently cleaning the facing surfaces intended to constitute a debondable interface. In the case of wet chemical cleaning, two cleaning compositions can be used: H₂SO₄, H₂O₂, H₂O or NH₄OH, H₂O₂, H₂O. If necessary, the surfaces are then rinsed with water and dried. The person skilled in the art knows how to adapt the mode of cleaning as a function of what is required.

The surfaces to be bonded are advantageously hydrophilic after cleaning.

Once the surface treatment has been effected, the prepared faces of the two surfaces of the plates are brought into contact to proceed to the direct bonding.

The two plates bonded in this way can be annealed, if required, to increase the bonding energy. For example, annealing at 420° C. is carried out for 30 minutes.

One of the two plates, here the top plate, is then thinned to the thickness of glass required for the final device, by any appropriate known mechanical and/or chemical technique. This step is optional if the plate concerned has the required thickness from the outset.

For example, one of the substrates is thinned to 100 μm, 75 μm or 64 μm.

The thickness of the thinned plate, here the top plate 32, given the properties of the glass used, is such that this plate has a flexibility compatible with the intended application of the finished product; this thickness is in practice at most equal to 100 microns and preferably at most equal to 50 microns; it is therefore correct to define the thinned top plate 32 as being a thin glass film. By comparison, the bottom plate 31 is a rigid bulk plate.

The stack shown in FIG. 2 is then obtained, in which the surface areas 31A and 32A of the two plates affected by the bonding conjointly form a bonding interface 33.

This interface is debondable, or reversible, by virtue of the measures taken to prepare the surfaces. It will be evident to the person skilled in the art how to draw inspiration from the teachings of the aforementioned PCT patent publication no. WO-02/084722 to control the bonding energy of this interface properly. For example, the bonding energy is very low, of the order of 350 mJ/m².

In one embodiment, the bonding energy is controlled by operating beforehand on the microroughness of the faces to be assembled. There is deposited onto one of the glass layers before bonding a layer of one or more oxides (for example SiO₂) the microroughness of which is adjusted. The person skilled in the art knows how to adjust the microroughness, by modifying the thickness of the deposited layer and/or using a specific chemical treatment (for example attack with hydrofluoric acid HF). If the oxide used is SiO₂, the person skilled in the art can further opt to apply or not heat treatment to impart to the SiO₂ layer the properties of thermal silica (see for example the paper “Bonding energy control: an original way to debondable substrates”; in Semiconductor Wafer Bonding: Science, Technology and Applications VII, Bengtsson ed, The Electrochemical Society 2003, p. 49, given at the Paris conference of the Electrochemical Society in May 2003).

In a different embodiment, the bonding energy is controlled by operating on the microroughness of the faces to be assembled and then carrying out cleaning as described hereinabove.

The basic substrate 31-32 is then used like a standard glass plate to fabricate an active matrix with thin layer components, here of TFT type. It is clear that the presence of the debondable interface does not significantly modify the mechanical properties of the stack compared to a one-piece plate of the same thickness. Alternatively, it is of course possible to use for the bottom plate a material other than glass but the stack of which with the top plate can undergo the same mechanical and heat treatments as the stack 31-32: the person skilled in the art knows how to evaluate the characteristics required for this kind of stack (in particular the nature and the thicknesses of the materials to be adopted and the associated thermal limitations).

### Fabrication of the TFT Active Matrix

FIG. 3 represents an active matrix plate after producing an array of TFT components corresponding to pixels from amorphous silicon using the bottom gate technology.

Other technologies can be used, of course, such as the top gate technology. Similarly, the components can instead be based on other materials, in particular polycrystalline silicon.

Production conditions can be exactly the same as for fabrication on a standard glass substrate; in particular, the maximum temperature used can be the same (generally 300° C. to deposit layers using the PECVD technique). This is made possible by the nature of the (glass) layers of the basic substrate and by the capacity of reversible bonding to withstand these temperatures. Moreover, as indicated, the total thickness of the basic substrate is very similar to that of a glass plate conventionally used in this kind of processing (0.7 mm).

The perfect compatibility of processing with existing fabrication lines is a considerable advantage of the invention, especially with respect to processes necessitating the presence of a layer of plastic during fabrication of the TFT (in the “EPLAR” process).

Accordingly, as known in the art, this array of thin layer components includes:
1) a metal gate 41 deposited by any appropriate deposition technique on the free surface of the thin glass film,
2) an insulative gate layer 42, typically of silicon nitride SiNx,
3) areas of amorphous silicon 44 deposited on the insulative layer (stack of intrinsic and doped layers),
4) contacts 43 deposited by any appropriate technique on the silicon layer and forming metal sources and drains,
5) an insulative passivating layer 45 covering the insulative layer 42 and the contacts, and
6) pixel electrodes 46, of ITO type for example for an LCD screen, produced on this passivation layer by any appropriate known process.

For an OLED screen, the electrodes are of molybdenum or aluminum or any other conductive material enabling injection of holes or electrons into the OLED.

Transverse strands, such as the strands 47 (these transverse strands are not all represented in the figures, for reasons of the legibility thereof), are provided in the insulative layers to establish the appropriate connections.

The next step is to fabricate a display layer on this active matrix of TFT components.

### Fabrication of the OLED Screen

FIG. 4 represents the step of adding to the pixel electrodes localized layers comprising appropriate organic electroluminescent materials, in practice red (48A), green (48B) and blue (48C) in color to produce a color OLED screen. These localized layers can be organic layers with small molecules (which yield “OLED” components) or polymer layers (which yield “PLED” components). They can be deposited by evaporation, by ink jet or by a turntable coating process. For more details see the paper “High efficiency phosphorescent OLEDs and their addressing with Poly or amorphous TFTS”, M. Hack et al., Eurodisplay 2002 Conference, Proc p. 21-24, Nice, October 2002.

These localized layers are covered by a conductive layer forming a second electrode or counter-electrode, to be more precise a cathode 49, which here is a continuous plane above the localized layers. This cathode cooperates with the electrodes 46 to form electroluminescent components emitting green, red or blue light according to the material sandwiched in this way.

These OLED components are covered with an encapsulation layer 50, which can be of SiNx. In the present example light is emitted toward the bottom of the screen (bottom emission), which is not possible with the SUFTLA or EPLAR processes. It is nevertheless possible, by adapting the materials, to operate with top emission.

The screen formed by the superposition of the TFT components and the OLED components is then covered by one or more layers of plastic material 51 which has a protective function as well as providing a handle for subsequent manipulation of the structure. This layer is deposited by rolling, for example (in particular, by unrolling this layer and pressing it onto the deposit surface).

Fabrication of the screen further includes a step of connecting drivers to the screen; this can be done at this stage.

The product obtained after this stage includes the screen to be produced as well as the rigid glass bulk layer that facilitated manipulating the assembly during the various fabrication steps.

This rigid layer must next be separated from the screen as such.

### Separation

The separation step consists in separating the screen and the thin layer of thin glass from the rigid layer of thick glass.

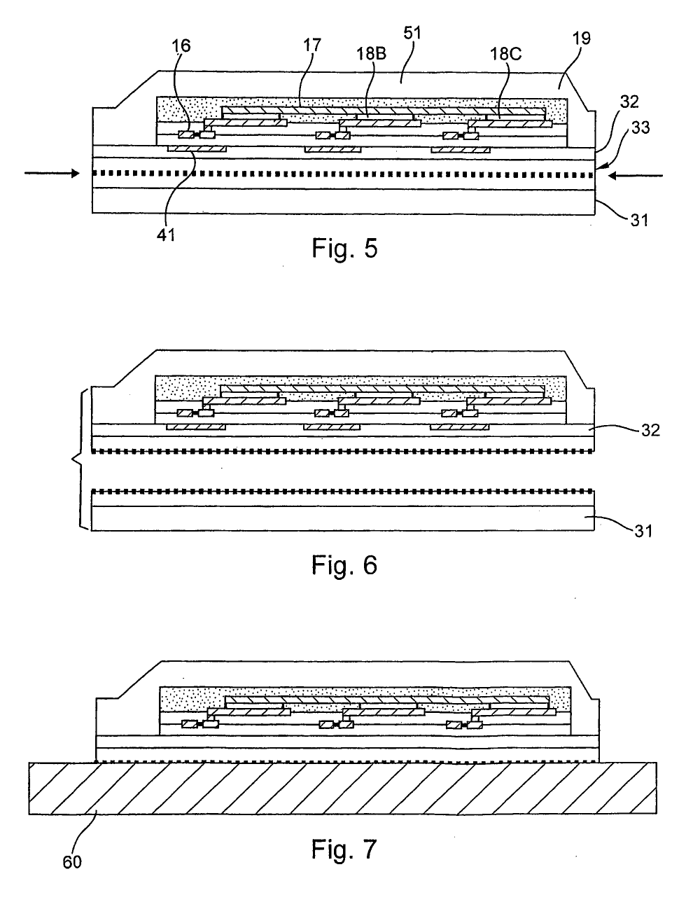

Separation is effected in the direct bonding area. It is advantageously effected by inserting a blade at the places indicated by arrows in FIG. 5. If the plastic encapsulation layer 50 is strong enough not to break during separation, there is no need to use a support handle glued on top as in the prior art processes.

FIG. 6 represents the result of this separation, at the place where the original plates were bonded.

In the embodiment specifically described, plates are therefore separated of which one has been thinned to 75 μm or 64 μm without breaking that plate.

It is interesting to note that, because the separation is the result of debonding of the interface initially obtained by bonding, the surfaces exposed by the separation are of good flatness and necessitate no costly planarization and/or cleaning treatment. Because of this they are in particular transparent in the case of bottom emission.

Thus the screen is separated from the glass substrate used to manipulate it during the fabrication steps. It is then possible to install this screen at its operating location.

### Transfer

The screen is then transferred onto a support 60 of any appropriate material, given the intended application, for example a plastic material support (see FIG. 7); this support is of polymer, for example, such as PET, for example.

This support 60 is preferably rolled onto the screen.

Comparing FIGS. 1 and 7 shows that the product obtained conforms well to the product required. There is seen the area 13 that is the surface area 32A of the plate 32 (see transfer of a basic substrate and FIG. 2) and which is the area of this plate 32 to which reversible bonding relates.

The screen, and therefore its thin layer of glass, can be fixed by bonding.

If a support is chosen that is flexible, because of its nature and/or its thickness (for example with a relatively small thickness in the range from 20 to 50 microns) a flexible screen is obtained.

Of course, the support can be more rigid, for example as a result of choosing greater thicknesses between 200 and 700 microns; the screen is then not particularly flexible, but nevertheless has the advantage of being light in weight and robust compared to an identical screen produced on a glass bulk support, with no separation.

It is therefore clear that, because the screen on its own is flexible, it is according to its application that the person skilled in the art will decide to retain one or both of these properties.

Thus the thin product obtained by the process of the invention can, alternatively as a function of requirements, be transferred in particular to materials such as a thin metal, for example stainless steel with a thickness advantageously between 50 and 200 microns, which preserves the quality of flexibility and improves the robustness and thermal stability of the assembly.

Clearly, although the description has just been given with respect to an OLED or PLED screen, it will be obvious to the person skilled in the art how to adapt the above teachings under item 3 to other applications, such as fabricating electrophoretic, LCD or PDLC screens:

1) for an electrophoretic screen: deposition of an electrophoretic layer by rolling, for example,

2) for an LCD screen, various technologies are possible (TN, PDLC, STN, etc.); the person skilled in the art will know how to adapt the process accordingly. For the TN technology: bonding a thin plate of colored filters (for example of glass) and filling with liquid crystal (for more details see “Liquid Crystal Displays, Addressing Schemes and Electrooptical Effects”, Ernst Lueder, Wiley Editor, June 2001).

Of course, the debondable interface can be produced, instead of directly between bared faces of two glass plates, indirectly, between attachment layers deposited on the faces to be fastened together.

The invention has various advantages, including:

1) if the thin glass film is attached to a rigid glass plate, the resulting support is completely compatible with known TFT processes, yielding a moderate cost and transistors produced at the standard temperatures and therefore of good quality,

2) effecting separation at a debondable interface ensures excellent control over the thickness of the residual thin layer, in particular to guarantee, if required, a particular level of flexibility, so that the performance obtained can be closely controlled,

3) the process of the invention is significantly less costly than the prior art “SUFTLA” and “EPLAR” processes, even though designed for similar applications, by virtue of the fact that it is not necessary to provide laser equipment,

4) bottom emission (see above and FIGS. 1 to 7) is possible for OLED and other screens,

5) the process of the invention can be used without limitations on the dimensions of the device to be produced; it is therefore possible to produce devices with a width and length of several centimeters or even several tens of centimeters.

1. A process for fabricating a flexible electronic device of the screen type, including a plurality of thin layer components on a glass support, the process comprising:
preparing a starting support including a rigid bulk substrate and a glass film attached to the rigid bulk substrate by reversible direct bonding to obtain a debondable interface;
fabricating the plurality of thin layer components on the glass film; and
separating the glass film from the rigid bulk substrate by debonding the interface.

2. The process according to claim 1, further comprising transferring a glass film and the plurality of thin layer components onto a final support.

3. The process according to claim 1, wherein preparing the starting support comprises bonding the glass film to a rigid glass substrate.

4. The process according to claim 1, wherein preparing a starting support further comprises performing a preparation treatment adapted to render surfaces to be bonded hydrophilic prior to the reversible direct bonding.

5. The process according to claim 1, wherein surfaces to be bonded have a roughness less than one nanometer.

6. The process according to claim 5, wherein the roughness of the surfaces to be bonded is less than 0.5 nanometer.

7. The process according to claim 1, wherein preparing the starting support further comprises bonding the rigid bulk support to a glass plate and applying a thinning treatment to the thickness of the glass plate to a required value.

8. The process according to claim 1, wherein the glass film has a thickness at most equal to 100 microns.

9. The process according to claim 8, wherein the glass film has a thickness at most equal to 50 microns.

10. A process according to claim 1, wherein fabricating a plurality of thin layer components comprises a step of fabricating an active matrix of pixels on the glass film and a step of fabricating a display layer on top of the active matrix of pixels, whereby an active matrix screen is obtained after separating the glass film.

11. The process according to claim 10, wherein fabricating the active matrix of pixels comprises forming components in TFT type thin layers.

12. The process according to claim 10, wherein fabricating the display layer comprises forming organic light-emitting components of OLED type.

13. The process according to claim 1, further comprising depositing an electrophoretic layer by a rolling process to obtain an electrophoretic screen.

14. The process according to claim 1, wherein an LCD screen is produced.

15. The process according to claim 1, wherein separating the glass film from the rigid bulk support comprises inserting a blade.

16. The process according to claim 1, further comprising transferring the glass film and the components that are formed thereon to a flexible plastic material film.

17. The process according to claim 1, further comprising transferring the glass film and the components that are formed thereon to a flexible metal film.

18. A flexible electronic device of the screen type comprising a plurality of thin layer electronic components on a support comprising a glass film having a thickness at most equal to 100 microns, such that significant flexibility it is imparted thereto.

19. The device according to claim 18, wherein the glass film has a thickness at most equal to 50 microns.

20. The device according to claim 18, wherein the plurality of components include a layer formed of an active matrix of pixels and a display layer covering the active matrix of pixels.

21. The device according to claim 18, wherein the device comprises an organic light-emitting diode screen.

22. The device according to claim 18, wherein the device comprises an electrophoretic screen.

23. The device according to claim 18, wherein the device comprises an LCD screen.

24. The device according to claim 18, wherein the electronic components emit light through the glass film.

25. A starting support for fabricating a thin layer flexible electronic device of the screen type by the process according to claim 1 including a rigid bulk substrate and a glass film fastened to the rigid bulk substrate by direct reversible bonding to obtain a debondable interface.

26. The support according to claim 25, wherein at least the surface of the rigid substrate comprises glass.
